(19) United States
(12) Patent Application Publication
(10) Pub. No.: US 2021/0003511 A1
(43) Pub. Date: Jan. 7, 2021

(54) DETECTION OF DAMAGE TO OPTICAL ELEMENT OF ILLUMINATION SYSTEM

(71) Applicant: Continental Automotive Systems, Inc., Auburn Hills, MI (US)

(72) Inventor: Jacob A. Bergam, Santa Barbara, CA (US)

(73) Assignee: Continental Automotive Systems, Inc., Auburn Hills, MI (US)

(21) Appl. No.: 16/502,839

(22) Filed: Jul. 3, 2019

(51) Int. Cl. G01N 21/88

(52) U.S. Cl. CPC G01N 21/8806; G01N 2021/8841

(57) ABSTRACT

A Lidar system includes an illumination system that includes a optical element and a light emitter aimed at the optical element. An exit window is positioned to receive light directed from the optical element. The illumination system may include a light-receiving element including a beam dump and/or a photodetector. The light-receiving element is positioned to receive light directed from the optical element. The light-receiving element and the exit window are on the same side of the optical element. The illumination system may include a light shield between the photodetector and the exit window. The light shield is positioned to shield the photodetector from light passing through the exit window.

### BACKGROUND

A solid-state Lidar system includes a photodetector, or an array of photodetectors that is essentially fixed in place relative to a carrier, e.g., a vehicle. Light is emitted into the field of view of the photodetector and the photodetector detects light that is reflected by an object in the field of view. For example, a Flash Lidar system emits pulses of light, e.g., laser light, into essentially the entire field of view. The detection of reflected light is used to generate a 3D environmental map of the surrounding environment. The time of flight of the reflected photon detected by the photodetector is used to determine the distance of the object that reflected the light.

The solid-state Lidar system may be mounted on a vehicle to detect objects in the environment surrounding the vehicle and to detect distances of those objects for environmental mapping. The output of the solid-state Lidar system may be used, for example, to autonomously or semi-autonomously control operation of the vehicle, e.g., propulsion, braking, steering, etc. Specifically, the system may be a component of or in communication with an advanced driver-assistance system (ADAS) of the vehicle.

### BRIEF DESCRIPTION OF THE DRAWINGS

FIG. 1 is a perspective view of a vehicle including a Lidar system.

FIG. 2 is perspective view of an illumination system of the Lidar system.

FIG. 3 is a perspective view of another embodiment of the illumination system.

FIG. 4 is a perspective view of another embodiment of the illumination system.

FIG. 5A is a schematic view of an embodiment of the illumination system with an optical element intact.

FIG. 5B is a schematic view of the embodiment of FIG. 5A with an optical element damaged.

FIG. 6A is a schematic view of another embodiment of the illumination system with an optical element intact.

FIG. 6B is a schematic view of the embodiment of FIG. 6A with the optical element damaged.

FIG. 7A is a schematic view of another embodiment of the illumination system with an optical element intact.

FIG. 7B is a schematic view of the embodiment of FIG. 7A with the optical element damaged.

FIG. 8A is a schematic view of another embodiment of the illumination system with the optical element intact.

FIG. 8B is a schematic view of the embodiment of FIG. 8A with the optical element damaged.

FIG. 9 is a block diagram of the Lidar system.

FIG. 10 is a method performed by the Lidar system and/or the vehicle.

### DETAILED DESCRIPTION

With reference to the Figures, wherein like numerals indicate like parts throughout the several views, a system 10 is generally shown. The system 10 may be a component of a light detection and ranging (Lidar) system 12. Specifically, the system 10 may be an illumination system of the Lidar system 12. The system 10 includes an optical element 14 and a light emitter 16 aimed at the optical element 14. An exit window 18 is positioned to receive light directed from the optical element 14.

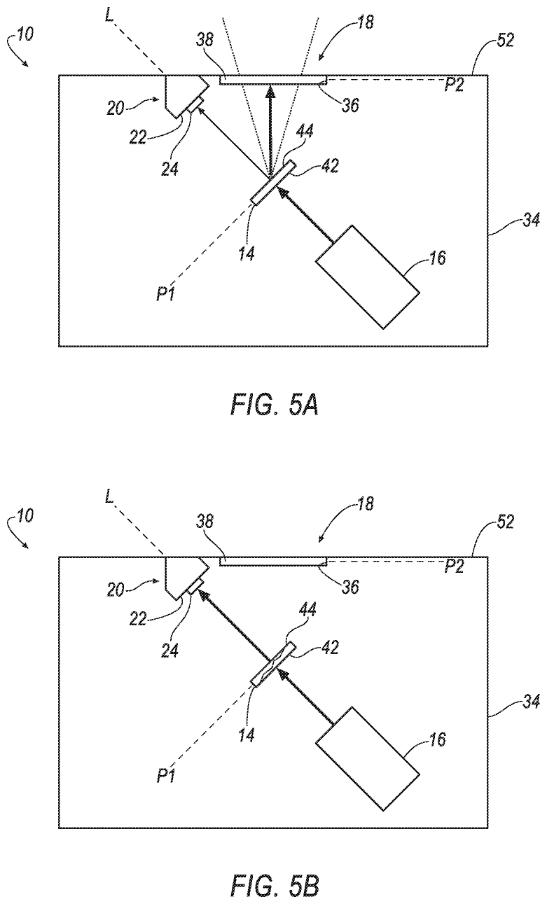

The system 10 may include a light-receiving element 20 including a beam dump 22 and/or a photodetector 24. The light-receiving element 20 is positioned to receive light directed from the optical element 14. The light-receiving element 20 and the exit window 18 are on the same side of the optical element 14, as described further below. In such a configuration, as shown in the examples in FIGS. 5A-8B, the optical element 14 receives light from the light emitter 16, shapes the light, and directs the light to the exit window 18. The optical element 14 may also direct some of the light from the light emitter 16 to the light-receiving element 20. Since the light-receiving element 20 and the exit window 18 are on the same side of the optical element 14, if the optical element 14 is damaged (FIGS. 5B, 6B, 7B, 8B) then the optical element 14 directs substantially all of the light emitted from the light emitter 16 to the light-receiving element 20. This prevents substantially all or all of the unshaped light (e.g., undiffused, unscattered, etc.) from the light emitter 16 from exiting the exit window 18.

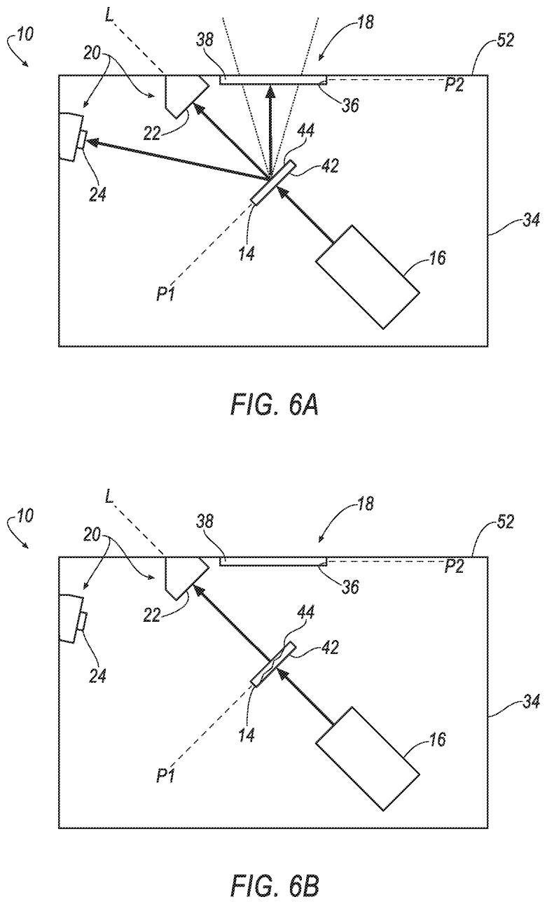

For example, in FIGS. 5A and 6A, the optical element 14 is undamaged and the light receiving element is positioned to receive zeroth order light from the optical element 14. When the optical element 14 is undamaged, the optical element 14 transmits the light from the light emitter 16 through the optical element 14 and shapes (e.g., diffuses, scatters, etc.) the light to the exit window 18. When the optical element 14 is damaged, as shown in FIGS. 5B and 6B, the optical element 14 does not shape e.g., does not diffuse or scatter) the light from the light emitter 16 and instead transmits substantially all of the light from the light emitter 16 to the light-receiving element 20.

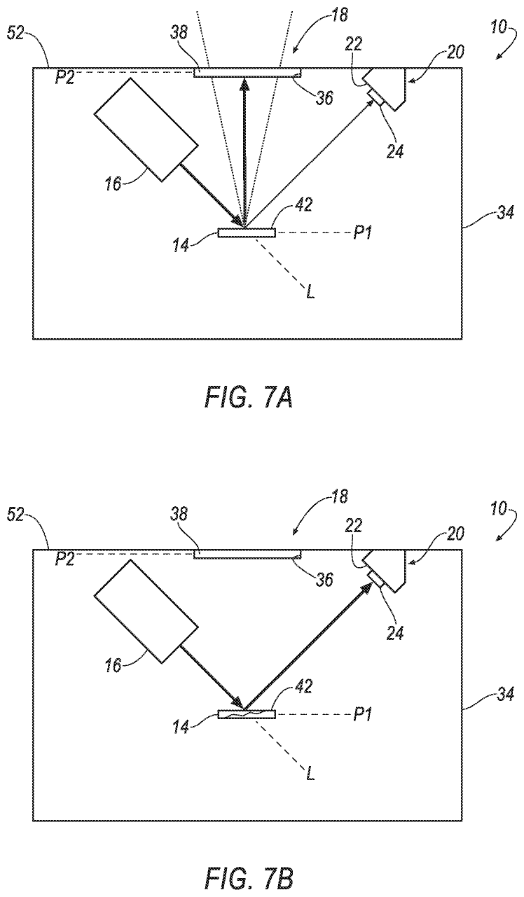

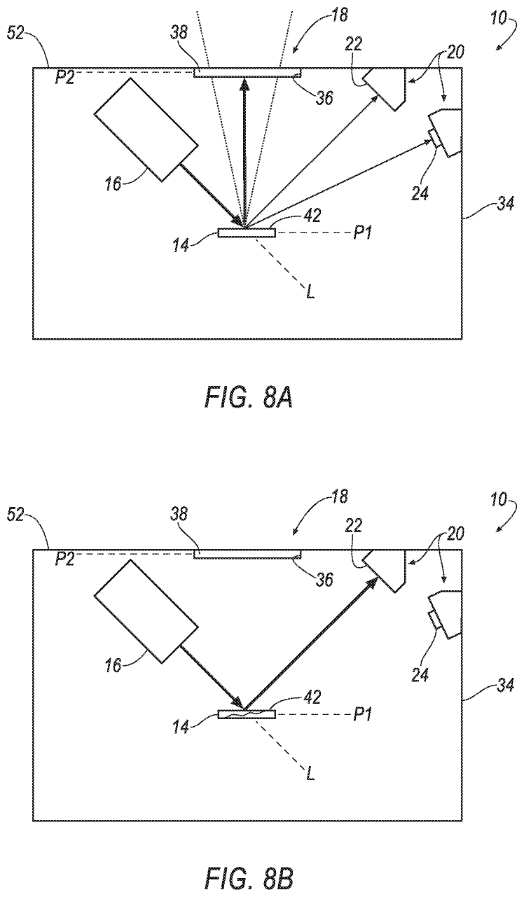

As other examples shown in FIGS. 7A-B and 8A-B, the optical element 14 reflects light from the light emitter 16. When the optical element 14 is undamaged, as shown in FIGS. 7A and 8A, the optical element 14 reflects and shapes (e.g., diffuses, scatters, etc.) a large portion of the light from the light emitter 16 to the exit window 18 and reflects a small portion of the light from the light emitter 16 to the light-receiving element 20. When the optical element 14 is damaged, as shown in FIGS. 7B and 8B, the optical element 14 does not shape (e.g., does not diffuse or scatter) the light from the light emitter 16 and instead reflects substantially all of the light from the light emitter 16 straight to the light-receiving element 20.

As set forth above, the light-receiving element 20 may include the photodetector 24. As described further below, the detection of light from the light emitter 16 by the photodetector 24 may be used, for example, to calculate time-of-flight and/or to monitor the integrity of the optical element 14. In such an example, the system 10 may include a light shield 26 between the photodetector 24 and the exit window 18, as described further below. The light shield 26 is positioned to shield the photodetector 24 from light passing through the exit window 18, i.e., exterior light shining into the exit window 18. The light shield 26 prevents interference by exterior light such that substantially all of the light detected by the photodetector 24 is emitted from the light emitter 16. This improves the accuracy of the calculation based on detection of light by the photodetector 24.

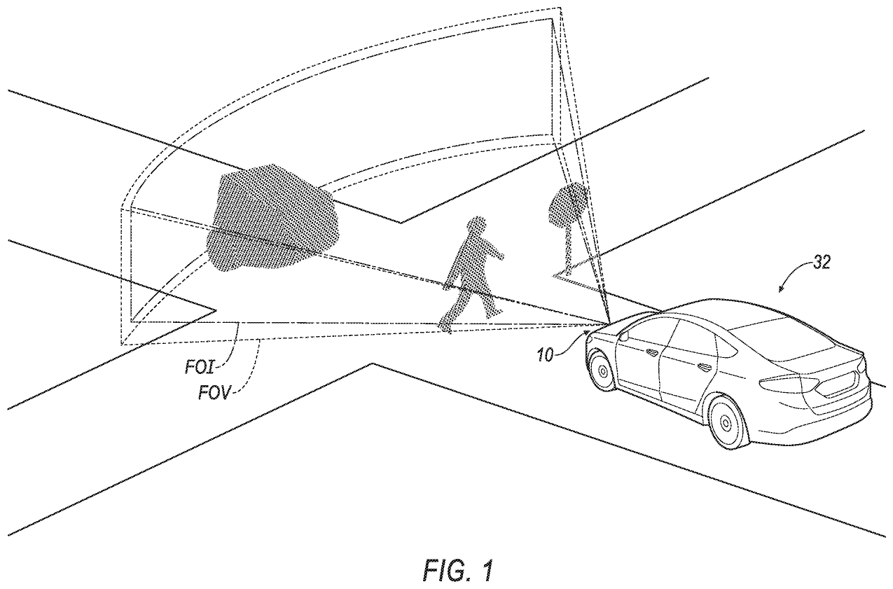

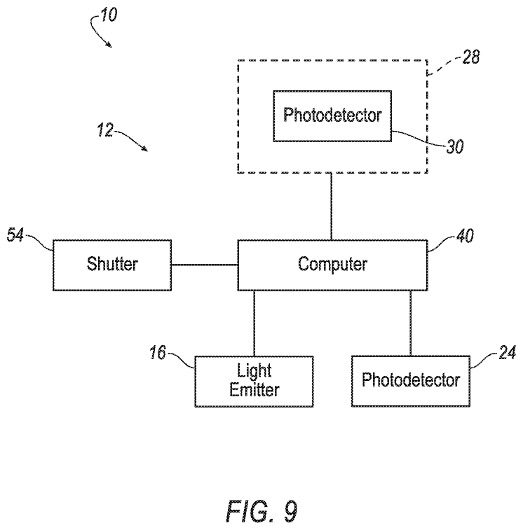

As set forth above, the system 10 may be a component of a Lidar system 12. As other example, the system 10 may be a component of an illumination system, e.g., visible illumination generated by the light emitter 16. As another example, the system 10 may be a component of a display device, e.g., a visible display screen in which the visible light is generated the light emitter 16. With reference to FIG. 1, the Lidar system 12 emits light and detects the emitted light that is reflected by an object, e.g., pedestrians, street signs, vehicles, etc. Specifically, light from the light emitter 16 is directed through the exit window 18 to a field of illumination FOI. The Lidar system 12 includes a light-receiving unit 28 (shown in FIG. 9 and described below) that has a field of view FOV that overlaps the field of illumination FOI and receives the reflected light. The light-receiving unit 28 may include a photodetector 30 (FIG. 9) and receiving optics (not shown), as are known. A computer 40 is in communication with the light emitter 16 for controlling the emission of light from the light emitter 16. The computer 40 may be a component of the system 10 and/or the Lidar system 12.

The Lidar system 12 is shown in FIG. 1 as being mounted on a vehicle 32. In such an example, the Lidar system 12 is operated to detect objects in the environment surrounding the vehicle 32 and to detect distance of those objects for environmental mapping. The output of the Lidar system 12 may be used, for example, to autonomously or semi-autonomously control operation of the vehicle 32, e.g., propulsion, braking, steering, etc. Specifically, the Lidar system 12 may be a component of or in communication with an advanced driver-assistance system 10 (ADAS) of the vehicle 32. The Lidar system 12 may be mounted on the vehicle 32 in any suitable position (as one example, the Lidar system 12 is shown on the front of the vehicle 32 and directed forward). The vehicle 32 may have more than one Lidar system 12 and/or the vehicle 32 may include other object detection systems, including other Lidar systems. The vehicle 32 is shown in FIG. 1 as including a single Lidar system 10 aimed in a forward direction merely as an example. The vehicle 32 shown in the Figures is a passenger automobile. As other examples, the vehicle 32 may be of any suitable manned or un-manned type including a plane, satellite, drone, watercraft, etc.

The Lidar system 12 may be a solid-state Lidar system. In such an example, the Lidar system 12 is stationary relative to the vehicle 32. For example, the Lidar system 12 may include a casing 34 (described below) that is fixed relative to the vehicle 32, i.e., does not move relative to the component of the vehicle 32 to which the casing 34 is attached, and a silicon substrate of the Lidar system 12 is supported by the casing 34.

As a solid-state Lidar system, the Lidar system 12 may be a flash Lidar system. In such an example, the Lidar system 12 emits pulses of light into the field of illumination FOI. More specifically, the Lidar system 12 may be a 3D flash Lidar system that generates a 3D environmental map of the surrounding environment, as shown in part in FIG. 1. An example of a compilation of the data into a 3D environmental map is shown in the field of view FOV and the field of illumination FOI in FIG. 1.

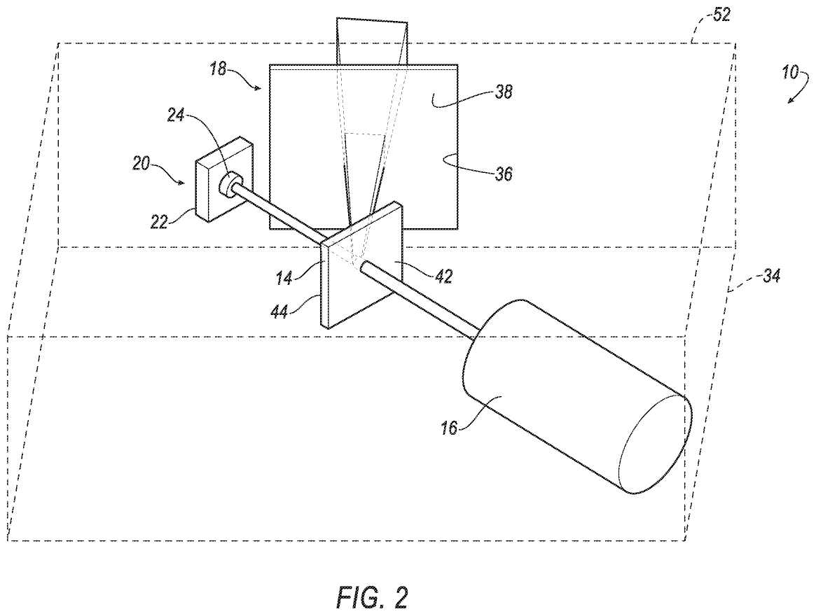

In such an example, the Lidar system 12 is a unit. For example, with reference to FIGS. 2-8A, the casing 34 may enclose the other components of the Lidar system 12 and may include mechanical attachment features to attach the casing 34 to the vehicle 32 and electronic connections to connect to and communicate with electronic system 10 of the vehicle 32, e.g., components of the ADAS. For example, the exit window 18 extends through the casing 34 and the casing 34 houses the optical element 14, the light emitter 16, and the light-receiving element 20. The exit window 18 includes an aperture 36 extending through the casing 34 and may include a lens 38 in the aperture 36.

The casing 34, for example, may be plastic or metal and may protect the other components of the Lidar system 12 from environmental precipitation, dust, etc. In the alternative to the Lidar system 12 being a unit, components of the Lidar system 12, e.g., the light emitter 16 and the light-receiving unit 28, may be separated and disposed at different locations of the vehicle 32.

With continued reference to FIG. 1, the light emitter 16 emits light into the field of illumination FOI for detection by the light-receiving unit 28 when the light is reflected by an object in the field of view FOV. The light emitter 16 may be, for example, a laser. The light emitter 16 may be, for example, a semiconductor laser. In one example, the light emitter 16 is a vertical-cavity surface-emitting laser (VCSEL). As another example, the light emitter 16 may be a diode-pumped solid-state laser (DPSSL). As another example, the light emitter 16 may be an edge emitting laser diode. The light emitter 16 may be designed to emit a pulsed flash of light, e.g., a pulsed laser light. Specifically, the light emitter 16, e.g., the VCSEL or DPSSL or edge emitter, is designed to emit a pulsed laser light. The light emitted by the light emitter 16 may be, for example, infrared light. Alternatively, the light emitted by the light emitter 16 may be of any suitable wavelength. The Lidar system 12 may include any suitable number of light emitters 16, i.e., one or more in the casing 34. In examples that include more than one light emitter 16, the light emitters 16 may be identical or different.

With reference to FIGS. 2-8A, the light emitter 16 may be stationary relative to the casing 34. In other words, the light emitter 16 does not move relative to the casing 34 during operation of the system 10, e.g., during light emission. The light emitter 16 may be mounted to the casing 34 in any suitable fashion such that the light emitter 16 and the casing 34 move together as a unit.

As set forth above, the system 10 may be a staring, non-moving system 10. As another example, the system 10 may include elements to adjust the aim of the system 10. For example, the Lidar system 12 may include a beam steering device (not shown) that directs the light from the light emitter 16 into the field of illumination FOI. The beam steering device may be a micromirror. For example, the beam steering device may be a micro-electro-mechanical system 10 (MEMS) mirror. As an example, the beam steering device may be a digital micromirror device (DMD) that includes an array of pixel-mirrors that are capable of being tilted to deflect light. As another example, the MEMS mirror may include a mirror on a gimbal that is tilted, e.g., by application of voltage. As another example, the beam steering device may be a liquid-crystal solid-state device.

As set forth above, the light emitter 16 is aimed at the optical element 14. In other words, light from the light emitter 16 is directed by the optical element 14, e.g., by transmission through and shaping (e.g., diffusion, scattering, etc.) by the optical element 14 (FIGS. 2-4, 5A, 6A) or by reflection and shaping (e.g., diffusion, scattering, etc.) by the optical element 14 (FIGS. 7A and 8A). The light emitter 16 may be aimed directly at the optical element 14 or may be aimed indirectly at the optical element 14 through intermediate reflectors/deflectors, diffusers, optics, etc.

The optical element 14 shapes light that is emitted from the light emitter 16. Specifically, the light emitter 16 is aimed at the optical element 14, i.e., substantially all of the light emitted from the light emitter 16 hits the optical element 14. As one example of shaping the light, the optical element 14 diffuses the light, i.e., spreads the light over a larger path and reduces the concentrated intensity of the light. As another example, the optical element 14 scatters the light, e.g., a hologram). “Unshaped light” is used herein to refer to light that is not shaped, e.g., not diffused or scattered, by the optical element 14, e.g., resulting from damage to the optical element 14. Light from the light emitter 16 may travel directly from the light emitter 16 to the optical element 14 or may interact with additional components between the light emitter 16 and the optical element 14. The shaped light from the optical element 14 may travel directly to the exit window 18 or may interact with additional components between the optical element 14 the exit window 18 before exiting the exit window 18 into the field of illumination FOI.

The optical element 14 directs at least some of the shaped light, e.g., the large majority of the shaped light, to the exit window 18 for illuminating the field of illumination exterior to the Lidar system 12. In other words, the optical element 14 is designed to direct at least some of the shaped light to the exit window 18, i.e., is sized, shaped, positioned, and/or has optical characteristics to direct at least some of the shaped light to the exit window 18.

As one example, the optical element 14 may be transmissive, as shown in FIGS. 2-6B. In such an example, the light from the light emitter 16 travels through the optical element 14 toward the exit window 18. As another example, the optical element 14 may be reflective, as shown in FIGS. 7A-8B. In such an example, the light from the light emitter 16 is reflected by the optical element 14 toward the exit window 18.

The optical element 14 may be of any suitable type that shapes and directs light from the light emitter 16 toward the exit window 18. For example, the optical element 14 may be or include a diffractive optical element, a diffractive diffuser, a refractive diffuser, a computer-generated hologram, a blazed grating, etc.

As set forth above, the light-receiving element 20 includes the beam dump 22 and/or the photodetector 24. The light-receiving element 20 is any suitable structure that detects light emitted from the light emitter 16 and/or absorbs light from the light emitter 16 to limit or prevent unshaped light from exiting the exit window 18. As described further below, the light-receiving element 20 is positioned to receive light directed from the optical element 14, e.g., at least when the optical element 14 is damaged. In other words, a portion of the light directed from the optical element 14 goes to the exit window 18 and a portion of the light directed from the optical element 14 goes to the light-receiving element 20 and not the exit window 18. In other words, the light directed from the optical element 14 to the light-receiving element 20 is interior light in the casing 34 that has not exited the exit window 18. In examples in which the light-receiving element 20 includes both the beam dump 22 and the photodetector 24, the beam dump 22 and the photodetector 24 may abut each other and/or integrated with each other, as shown in FIGS. 2-5B and 7A-B. As another example, the beam dump 22 and the photodetector 24 may be spaced from each other, as shown in FIGS. 6A-B and 8A-B. In any event, the light receiving element is fixed relative to the casing 34, i.e., does not move relative to the casing 34. In examples in which the light-receiving element 20 includes both the beam dump 22 and the photodetector 24, both the beam dump 22 and the photodetector 24 are fixed relative to the casing 34.

The beam dump 22 is designed to absorb some or all of the unshaped light emitted from the light emitter 16, i.e., when the optical element 14 is damaged and unshaped light is directed at the beam dump 22. The beam dump 22 may be of a material type, have surface characteristics, and/or shape and size to absorb the unshaped light. In such example, the beam dump 22 absorbs the unshaped light, i.e., when the optical element 14 is damaged, to limit or prevent unshaped light from exiting the casing 34 through the exit window 18.

The photodetector 24 detects light. The photodetector 24 is designed and positioned to detect zeroth order light from the optical element 14 (FIGS. 2-5A), shaped (e.g., diffused, scattered, etc.) light directed at the photodetector 24 from the optical element 14 when optical element 14 is undamaged (FIGS. 6A and 8A), and/or unshaped light from the light emitter 16 when the optical element 14 is damaged (FIGS. 5B and 7B). “Photodetector 24” includes a single photodetector 24 or an array of photodetectors 24 (including 1D arrays, 2D arrays, etc.). The photodetector 24 may be, for example, an avalanche photodiode detector or PIN detector. As one example, the photodetector 24 may be a single-photon avalanche diode (SPAD).

With reference to the examples in FIGS. 2-5A in which the light-receiving element 20 is positioned to receive zeroth order light from the optical element 14, zeroth order light, i.e., light in the zero order, refers to a portion of light from the light emitter 16, e.g., a very small portion of the light, that is transmitted through the optical element 14 without being shaped. In FIGS. 2-5A, the optical element 14 may be a diffractive optical element. The zeroth order light is undiffracted and behaves according to the laws of reflection and refraction. The zeroth order light may be a result of real-world and manufacturing capabilities of the optical element 14 that prevents 100% diffraction.

In the example shown in FIGS. 5A-B and 6A-B, the light emitter 16 is aimed along a line L, i.e., light emitted from the light emitter 16 is concentrated along the line L, and the light-receiving element 20 is on the line L. The optical element 14 is along the line L and the exit window 18 is offset from the line L. Specifically, the optical element 14 is centered on first plane P1 perpendicular to the line L and the exit window 18 is centered on a second plane P2 transverse to the first plane P1. The optical element 14 shapes (e.g., diffuses, scatters, etc.) a large portion of the light from the light emitter 16 toward the window, i.e., when the optical element 14 is intact.

With reference to FIGS. 5A-B, zeroth order light is transmitted through the optical element 14 generally along the line L to the light-receiving element 20. The beam dump 22 and the photodetector 24 are both on the line L in the example in FIGS. 5A-B. In this example, the photodetector 24 may detect the zeroth order light and this detection may be used by the computer 40, e.g., to start the clock (i.e., range detection timer) for TOF calculation. If the optical element 14 is damaged, i.e., such that the optical element 14 no longer shapes the light emitted by the light emitter 16, the light instead is transmitted through the optical element 14 undiffracted to the light-receiving element 20. In this scenario, the beam dump 22 absorbs the light, i.e., to limit or prevent the unshaped light from exiting at the exit window 18, and/or the photodetector 24 detects the relatively higher intensity of light. This detection may be used by the computer 40 to identify that the optical element 14 is damaged.

With reference to FIGS. 6A-B, the beam dump 22 is on the line L and the photodetector 24 is offset from the line L, i.e., substantially all of the unshaped light transmitted through the optical element 14 when the optical element 14 is damaged goes to the beam dump 22. In this example, the optical element 14, when undamaged, is designed to shape (e.g., diffuse, scatter, etc.) and direct a portion of the light from the light emitter 16, i.e., large portion of the light, to the exit window 18 and to direct a portion of the light from the light emitter 16, i.e., a small portion of the light, to the photodetector 24 (and in some embodiments also a small portion to the beam dump 22). The photodetector 24 may detect this light and this detection may be used by the computer 40, e.g., to start the clock for TOF calculation. If the optical element 14 is damaged, i.e., such that the optical element 14 does not shape the light emitted by the light emitter 16, the light instead is transmitted through the optical element 14 unshaped to the beam dump 22. In this scenario, the beam dump 22 absorbs the light, i.e., to limit or prevent the unshaped light from exiting at the exit window 18. The determination by the computer 40 that the photodetector 24 is not receiving light when the light emitter 16 is activated may be used by the computer 40 to identify that the optical element 14 is damaged. The photodetector 24 may be spaced from the beam dump 22, such as in the example in FIGS. 6A-B, because the undiffused light may damage the photodetector 24 and/or not be properly detected by the photodetector 24.

With continued reference to FIG. 6A, the optical element 14 may be designed to shape the light and direct the light to the exit window 18, the photodetector 24, and optionally the beam dump 22. This design of the optical element 14 may be a natural result of real-world imperfections in the manufacturing process. As another example, this design of the optical element 14 may be an engineered design. For example, the optical element 14 may split the light emitted by the light emitter 16 into multiple orders (first, second, third, etc.) with different orders directed toward different ones of the exit window 18, the photodetector 24, and optionally the beam dump 22, respectively. In the example shown in FIGS. 7A-B and 8A-B, the light emitter 16 is aimed at the optical element 14 and the optical element 14 shapes and reflects a portion of the light, i.e., a large portion of the light, toward the exit window 18. In these examples, the optical element 14 is designed to reflect substantially all unshaped light to the light-receiving element 20 when the optical element 14 is damaged, i.e., such that the optical element 14 does not the light emitted by the light emitter 16. In other words, the optical element 14 is sized, shaped, positioned, and/or has reflective properties to reflect substantially all unshaped light to the light receiving element when the optical element 14 is damaged.

With reference to FIGS. 7A-B, the beam dump 22 and the photodetector 24 abut each other and/or are integrated with each other. In this example, a small portion of light is reflected from the optical element 14 to the beam dump 22 and photodetector 24 when the optical element 14 is intact, as shown in FIG. 7A. If the optical element 14 is damaged, as shown in FIG. 7B, substantially all of the light emitted from the light emitter 16 is reflected, undiffused, to the beam dump 22 and the photodetector 24 for the purposes described above.

With reference to FIGS. 8A-B, the beam dump 22 and the photodetector 24 are spaced from each other. In this example, a small portion of light is reflected from the optical element 14 to the beam dump 22 and the photodetector 24 when the optical element 14 is intact, as shown in FIG. 8A. If the optical element 14 is damaged, as shown in FIG. 8B, substantially all of the light emitted from the light emitter 16 is reflected, undiffused, to the beam dump 22 for the purposes described above.

In the examples shown in FIGS. 2-8B, the light-receiving element 20 and the exit window 18 are on the same side of the optical element 14, i.e., a common side of the optical element 14. In other words, light exiting the optical element 14, either by transmission or reflection, exits the optical element 14 from one side to both the exit window 18 and the light-receiving element 20. In other words, in examples where the optical element 14 is transmissive (FIGS. 2-6B), the light emitter 16 is aimed at a first side 42 of the optical element 14 and the light-receiving element 20 and the exit window 18 are on a second side 44 of the optical element 14. In other word, shaped light exits the second side 44 to both the light-receiving element 20 and the exit window 18. In examples where the optical element 14 is reflective (FIGS. 7A-8B), the light emitter 16 is aimed at a first side 42 of the optical element 14 and the light-receiving element 20 and the exit window 18 are both on the first side 42 of the optical element 14. In other word, shaped light exits the first side 42 to both the light-receiving element 20 and the exit window 18.

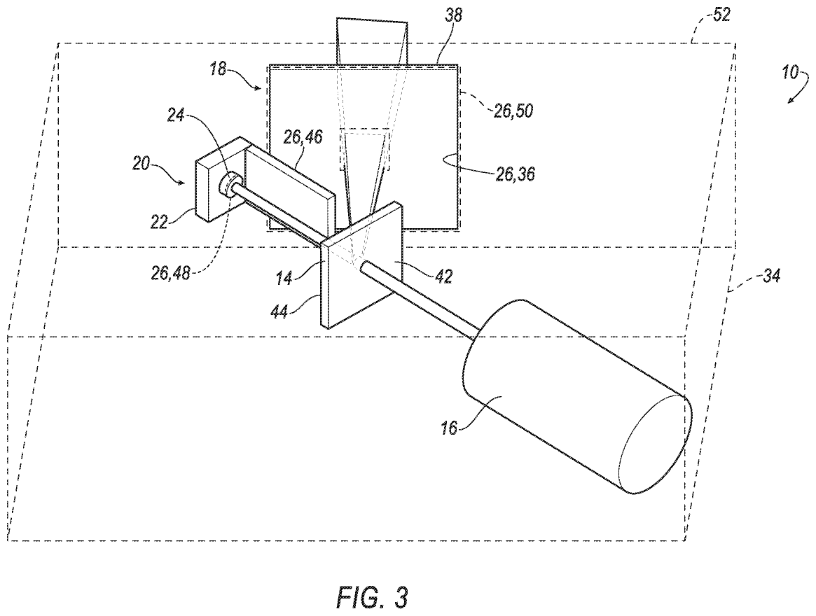

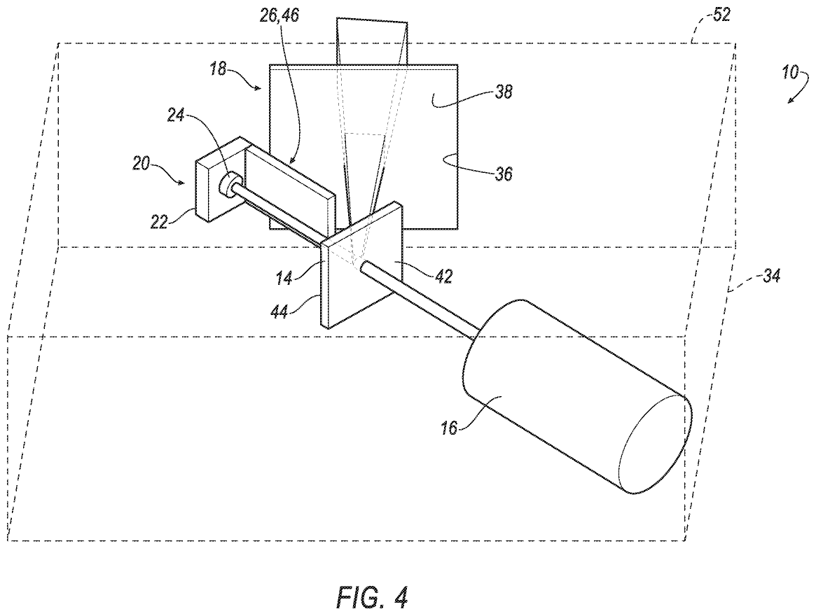

With reference to FIGS. 3 and 4, in examples where the light-detecting element includes the photodetector 24, the system 10 may include the light shield 26 positioned to shield the photodetector 24 from light passing through the exit window 18. In other words, the light shield 26 prevents light that enters into the casing 34 through the exit window 18 from being detected by the photodetector 24. The light shield 26 is between the photodetector 24 and the exit window 18. The light shield 26 is shown in FIGS. 3 and 4 with embodiments in which the optical element 14 is transmissive, and the light shield 26 may similarly be in the embodiments in which the optical element 14 is reflective, including in FIGS. 7A-8B.

With reference to FIG. 3, the light shield 26 may be a wall 46 in the casing 34, the aperture 36 having a design to limit light incoming at the exit window 18, and/or a bandpass filter 48. The example shown in FIG. 3 includes the wall 46, the aperture 36, and the bandpass filter 48; however, the system 10 may include any one of the wall 46, the aperture 36, and the bandpass filter 48 or any combination thereof. As just one example, the system 10 shown in FIG. 4 includes the wall 46 and not the aperture 36 of specific design or the bandpass filter 48.

With reference to FIGS. 3 and 4, the wall 46 is between the photodetector 24 and the exit window 18. The wall 46 is opaque to prevent light from passing through the exit window 18 to the photodetector 24. The wall 46 may be, for example, plastic, metal, etc. As one example, with reference to FIGS. 3 and 4, the wall 46 may be spaced from the exit window 18. In such an example, the wall 46 may extend from an exterior wall 52 of the casing 34 into the casing 34 between the photodetector 24 and the exit window 18, i.e., the wall 46 is an interior wall.

With reference to FIG. 3, the aperture 36 may be designed, i.e., sized, shaped, and angled, to limit light from passing into the casing 34 through the exit window 18 to the photodetector 24. As an example, the design of the aperture 36 may be defined by the exterior wall 52, i.e., the wall 52 is between the photodetector 24 and the exit window 18. The exterior wall 52 may include a wall of the casing 34 and/or may include a covering 50, e.g., on the lens 38, defining the design of the aperture 36 to limit incoming light. The covering 50 may be an opaque material on the surface of the lens 38, e.g., blackout material.

With reference to FIG. 3, the light shield 26 may a bandpass filter 48 between the photodetector 24 and the exit window 18. In such an example, the bandpass filter 48 is designed to transmit light in a bandwidth including the wavelength of light emitted by the light emitter 16. In other words, the bandpass filter 48 passes light from the light emitter 16 exiting the exit window 18 and attenuates light of other wavelengths from entering the casing 34 through the bandpass filter 48. The bandpass filter 48 may be at the aperture 36 (e.g., at or on the lens 38), adjacent the photodetector 24 (e.g., at or on the photodetector 24), or at any suitable location between the aperture 36 and the photodetector 24 to limit incoming light from reaching the photodetector 24. In the example shown in FIG. 3, the bandpass filter is adjacent the photodetector 24.

As another example, the light shield 26 may be a shutter 54 (FIG. 9). The shutter 54 may be located at the exit window 18. The shutter 54 may be opened to allow light to pass through the exit window 18 and closed to prevent light from passing through the exit window 18. In such an example, the shutter 54 may be closed in response to a detection of light, or lack of light, by the photodetector 24. For example, in the examples in FIGS. 5A-B and 7A-B, the shutter 54 may be closed when the photodetector 24 detects high-intensity light resulting from damage to the optical element 14 (FIGS. 5B and 7B). In the examples in FIGS. 6A-B and 8A-B, the shutter 54 may be closed when the photodetector 24 detects no light from the light emitter 16 resulting from damage to the optical element 14 (FIGS. 6B and 8B).

The computer 40 may be programmed to open the shutter 54 during normal operation of the system 10 and to close the shutter 54 when damage to the optical element 14 is detected. The computer 40 may be programmed to test the integrity of the system 10 when the shutter 54 is closed. For example, with the shutter 54 closed, the computer 40 may instruct the light emitter 16 to emit light for detection by the photodetector 24. This eliminates the possibility of light entering the exit window 18 and being detected by the photodetector 24. This can be used to confirm damage to the system 10, e.g., the optical element 14, by ruling out interference by incoming light through the exit window 18. When closed, the shutter 54 also prevents any potential unshaped light from exiting the exit window 18.

With reference to FIG. 9, the Lidar system 12 may include the computer 40. The computer 40 is in communication with the light emitter 16 for controlling the emission of light from the light emitter 16. The computer 40 may be in communication with the photodetector 24 for receiving detection of light emitted from the light emitter 16, e.g., in the casing 34. As an example, the computer 40 may instruct the light emitter 16 to emit light and may detect light with the photodetector 24, as described above. For example, the computer 40 may initiate the clock for TOF calculation based on detection of light by the photodetector 24, as described above. The computer 40 may be in communication with the light-receiving unit 28, e.g., the photodetector 30 that receive light reflected in the field of view FOV.

The computer 40 may be a microprocessor-based controller or field programmable gate array (FPGA), or a combination of both, implemented via circuits, chips, and/or other electronic components. In other words, the computer 40 is a physical, i.e., structural, component of the system 10. For example, the computer 40 includes a processor, memory, etc. The memory of the computer 40 may store instructions executable by the processor, i.e., processor-executable instructions, and/or may store data. The computer 40 may be in communication with a communication network of the vehicle 32 to send and/or receive instructions from the vehicle 32, e.g., components of the ADAS.

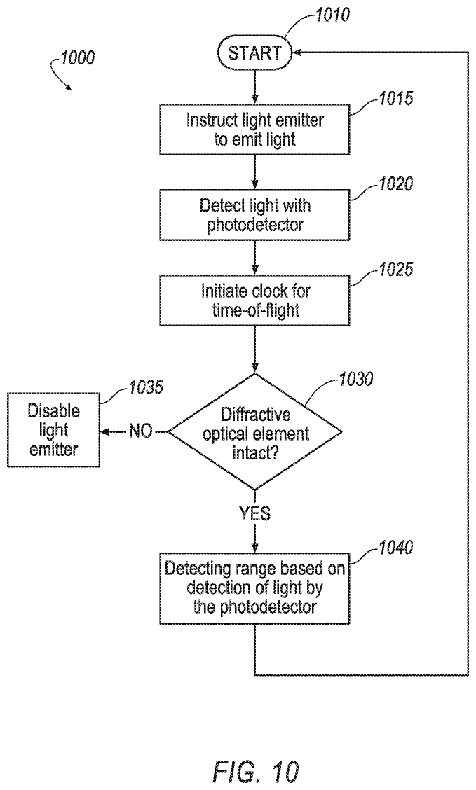

As set forth above, the computer 40 has a processor and memory storing instructions executable by the processor. Specifically, the instructions include instructions to perform the method 1000 in FIG. 10. Use herein (including with reference to the method 1000 in FIG. 10) of “based on,” “in response to,” and “upon determining,” indicates a causal relationship, not merely a temporal relationship.

With reference to FIG. 10, the method includes instructing the light emitter 16 to emit light, as shown in block 1015. The computer 40 may initiate the method 1000 in block 1010 based on, for example, instructions from an ADAS of the vehicle 32. When the light emitter 16 emits light, the light is aimed at the optical element 14, as described above.

With reference to block 1020, the method 1000 includes detecting light from the light emitter 16 in the casing 34 by the photodetector 24. Block 1020 may include detecting a condition of light or detecting the absence of light after instructing emission of light in block 1015. In response to the detecting light in block 1020, the method includes initiating a clock for TOF calculation in block 1025 (described further below) and determining if the optical element 14 is intact or damaged in block 1030.

With reference to decision block 1030, the instructions may include determining the integrity of the optical element 14, i.e., whether the optical element 14 is damaged, based on the condition of light (e.g., intensity of light, lack of any light, etc., detected by the photodetector 24), i.e., detecting damage to the optical element 14 based on intensity of the light detected by the photodetector 24. Specifically, the method 1000 includes (in block 1020 and/or block 1030) detecting a condition of light indicating the integrity of the optical element 14. As an example, the method may include identifying the light as being within an intensity range indicating that the optical element 14 is intact and/or may include identifying the light as being within an intensity range indicating that the optical element 14 is damaged. One of the intensity ranges may include zero intensity. As another example, the method may include identifying a change in intensity of light from the previous detection of light by the photodetector 24.

In the example shown in FIGS. 5A-B, zeroth order light reaches the photodetector 24 when the optical element 14 is intact (FIG. 5A) (i.e., the method may include detecting zeroth order light) and undiffused light is transmitted through the optical element 14 to the photodetector 24 when the optical element 14 is damaged (FIG. 5B). In the example shown in FIGS. 6A-B, the optical element 14 directs shaped light to the photodetector 24 when the optical element 14 is intact (FIG. 6A) and substantially no light from the light emitter 16 reaches the photodetector 24 when the optical element 14 is damaged (FIG. 6B). In the example shown in FIGS. 7A-B, the optical element 14 reflects shaped light to the photodetector 24 when the optical element 14 is intact (FIG. 7A) and reflects unshaped light to the photodetector 24 when the optical element 14 is damaged (FIG. 7B). In the example shown in FIGS. 8A-B, the optical element 14 reflects shaped light to the photodetector 24 when the optical element 14 is intact (FIG. 8A) and substantially no light from the light emitter 16 reaches the photodetector 24 when the optical element 14 is damaged. In each of these examples, the intensity of light detected by the photodetector 24 changes when the optical element 14 is damaged.

With continued reference to decision block 1030, the method 1000 includes determining whether the optical element 14 is intact. This step may include directly determining that the optical element 14 is intact or, conversely, directly determining that the optical element 14 is damaged and thus indirectly determining that the optical element 14 is intact. The determination of the integrity of the optical element 14 may be based on the detection of the light in block 1020. If the method 1000 determines that the optical element 14 is damaged, the method 1000 may include disabling the light emitter 16, as shown in block 1035. This may prevent further damage to components of the Lidar system 12 and prevents exiting of unshaped light through the exit window 18. Block 1035 may include closing the shutter 54. With the shutter 54 closed, block 1035 may include testing the integrity of the system 10, e.g. the optical element 14, as described above.

As set forth above, the method 1000 includes initiating the clock for TOF calculation based on the detection of light by the photodetector 24 in block 1025. The method 1000 may include detecting range of an object beyond the exit window 18 illuminated by the light emitter 16 based on detection of light by the photodetector 24, as shown in block 1030. Specifically, the range detection is based on the TOF of the detected photon by the light-receiving unit 28 of the Lidar system 12. The initiation of the TOF may be based on the clock initiated in block 1025.

The disclosure has been described in an illustrative manner, and it is to be understood that the terminology which has been used is intended to be in the nature of words of description rather than of limitation. Many modifications and variations of the present disclosure are possible in light of the above teachings, and the disclosure may be practiced otherwise than as specifically described.

What is claimed is:

1. A system comprising:
an optical element;
a light emitter aimed at the optical element;
a light-receiving element including a beam dump and/or a photodetector, the light-receiving element positioned to receive light directed from the optical element; and
an exit window positioned to receive light directed from the optical element;
the light-receiving element and the exit window being on the same side of the optical element.

2. The system as set forth in claim 1, wherein the light-receiving element includes the photodetector, the system further comprising a light shield positioned to shield the photodetector from light passing through the exit window.

3. The system as set forth in claim 2, wherein the light shield includes a wall between the photodetector and the exit window.

4. The system as set forth in claim 3, further comprising a casing, the exit window including an aperture extending through the casing, and the wall being in the casing and spaced from the aperture.

5. The system as set forth in claim 2, wherein the light shield is a bandpass filter between the photodetector and the exit window and designed to transmit light in a bandwidth including the wavelength of light emitted by the light emitter.

6. The system as set forth in claim 1, wherein the light-receiving element includes the photodetector, the system further comprising a casing, the exit window including an aperture extending through the casing, the aperture being sized to shield the photodetector from light passing through the exit window.

7. The system as set forth in claim 1, wherein the optical element is reflective and the light emitter is aimed at a first side of the optical element and the light-receiving element and the exit window are on the first side of the optical element.

8. The system as set forth in claim 1, wherein the optical element is transmissive and the light emitter is aimed at a first side of the optical element and the light-receiving element and the exit window are on a second side of the optical element.

9. The system as set forth in claim 1, wherein the light-receiving element is positioned to receive zeroth order light from the optical element.

10. The system as set forth in claim 1, wherein the light emitter is aimed along a line and the light-receiving element is on the line.

11. The system as set forth in claim 10, wherein the exit window is offset from the line.

12. The system as set forth in claim 10, wherein the optical element is centered on first plane perpendicular to the line and the exit window is centered on a second plane transverse to the first plane.

13. The system as set forth in claim 1, wherein the light-receiving element includes the photodetector, the system further comprising a computer having a processor and memory storing instructions executable by the processor, the instructions including determining the integrity of the optical element based on intensity of light detected by the photodetector.

14. The system as set forth in claim 1, wherein the light-receiving element includes the photodetector, and the instructions include detecting range of an object beyond the exit window illuminated by the light emitter based on detection of light by the photodetector.

15. The system as set forth in claim 1, further comprising a casing, wherein the exit window extends through the casing and the casing houses the optical element, the light emitter, and the light-receiving element.

16. A system comprising:
an optical element;
a light emitter aimed at the optical element;
a photodetector positioned to receive light directed from the optical element; and
an exit window positioned to receive light directed from the optical element;
a light shield between the photodetector and the exit window, the light shield positioned to shield the photodetector from light passing through the exit window.

17. The system as set forth in claim 16, wherein the light shield includes a wall between the photodetector and the exit window.

18. The system as set forth in claim 17, further comprising a casing, the exit window including an aperture extending through the casing, and the wall being in the casing and spaced from the exit window.

19. The system as set forth in claim 16, wherein the light shield is a bandpass filter between the photodetector and the exit window and designed to transmit light in a bandwidth including the wavelength of light emitted by the light emitter.

20. The system as set forth in claim 16, further comprising a casing, the light shield including a wall defining an aperture of the exit window, the aperture being sized to shield the photodetector from light passing through the exit window.

21. The system as set forth in claim 16, wherein the light shield is between the photodetector and the exit window.

22. The system as set forth in claim 16, wherein the light-receiving element is positioned to receive zeroth order light from the optical element.

23. The system as set forth in claim 16, wherein the light emitter is aimed along a line and the light-receiving element is on the line.

24. The system as set forth in claim 23, wherein the exit window is offset from the line.

25. The system as set forth in claim 23, wherein the optical element is centered on first plane perpendicular to the line and the exit window is centered on a second plane transverse to the first plane.

26. A method comprising:
aiming light from a light emitter to an optical element and from the optical element through an exit window;
detecting light from the light emitter directed from the optical element to a photodetector spaced from the exit window; and
detecting a range of an object illuminated by the light emitted through the exit window based on the detection of light by the photodetector.

27. The method as set forth in claim 26, further comprising initiating a range detection timer based on the detection of light by the photodetector.

28. The method as set forth in claim 26, further comprising detecting damage to the optical element based on intensity of the light detected by the photodetector.

29. The method as set forth in claim 26, wherein detecting light directed from the optical element to the photodetector includes detecting zeroth order light.
